(19) United States
(12) Patent Application Publication
(10) Pub. No.: US 2011/0227458 A1
(43) Pub. Date: Sep. 22, 2011

(54) PIEZOELECTRIC RESONATOR ELEMENT, PIEZOELECTRIC DEVICE, AND ELECTRONIC APPARATUS

(75) Inventor: Hideo TANAYA, Suwa-shi (JP)

(73) Assignee: SEIKO EPSON CORPORATION, TOKYO (JP)

(21) Appl. No.: 13/041,815

(22) Filed: Mar. 7, 2011

(30) Foreign Application Priority Data
Mar. 17, 2010 (JP) 2010-060327
Dec. 28, 2010 (JP) 2010-292043

(51) Int. Cl. H01L 41/04; H01L 41/053

(52) U.S. Cl. 310/344; 310/370

(57) ABSTRACT

A piezoelectric resonator element and a piezoelectric device, which prevent the vibration of the resonating arm section from leaking to the side of the base portion and stabilize the vibration of the resonating arm section, and an electronic apparatus using these devices are obtained. The quartz crystal resonator element as the piezoelectric resonator element is provided with a base portion formed of a piezoelectric material, a plurality of resonating arm sections each extending from the base portion via an arm base section, and an elongated groove section formed along a longitudinal direction of the resonating arm section, and the arm base section has an arm width, which is larger than an arm width of the resonating arm section and smaller than a distance between imaginary centerlines of the respective resonating arm sections in a width direction of the resonating arm section.

### BACKGROUND

1. Technical Field

The present invention relates to a piezoelectric resonator element, a piezoelectric device, and an electronic apparatus using these components.

2. Related Art

In the past, the resonating arm section of the piezoelectric resonator element has been formed so as to extend from a base portion. Further, in order for preventing the stress concentration from occurring at the joint section between the resonating arm section and the base portion to thereby stabilize the vibration of the resonating arm section, a taper section (a reduced-width section) has been formed (see, e.g., JP-A-2005-5896 (pp. 5-7, FIGS. 1-5) and JP-A-2006-311090 (pp. 6-7, FIG. 3)). Further, there has been disclosed a piezoelectric resonator element having the resonating arm section formed to have an arm width gradually increasing in a direction from the resonating arm section toward the base portion (see, e.g., JP-A-2009-27711 (pp. 5-6, FIG. 1)).

However, in the case in which the taper section (the reduced-width section) is formed between the resonating arm section and the base portion, and in the case in which the resonating arm section is formed to have an arm width gradually increasing in the direction toward the base portion, there arises a problem that the vibration leakage is caused in the vibration of the resonating arm section at the base portion side, and it is difficult to obtain the piezoelectric resonator element having the resonating arm section the vibration of which is stabilized.

### SUMMARY

An advantage of some aspects of the invention is to solve at least a part of the problem described above, and the invention can be implemented as the following embodiments or application examples.

### APPLICATION EXAMPLE 1

According to this application example of the invention, there is provided a piezoelectric resonator element including a base portion formed of a piezoelectric material, and a plurality of resonating arm sections each extending from the base portion via an arm base section, wherein an elongated groove section is provided along a longitudinal direction of the resonating arm section, and the arm base section has an arm width, which is larger than an arm width of the resonating arm section and smaller than a distance between imaginary centerlines of the respective resonating arm sections in a width direction of the resonating arm section.

According to this application example of the invention, since the arm base sections each having the arm width larger than the arm width of the vibration arm section and smaller than the distance between the imaginary centerlines of the respective resonating arm sections in a width direction of the resonating arm section are provided, and the arm base sections each have a portion having a width larger than the arm width of the vibration arm section and having a certain length to thereby provide rigidity to the vibration arm sections, it is possible to prevent the vibration of the vibration arm section from leaking to the base portion to thereby stabilize the vibration of the vibration arm section and the vibrational frequency of the piezoelectric resonator element.

### APPLICATION EXAMPLE 2

According to this application example of the invention, in the piezoelectric resonator element of the above application example of the invention, it is preferable to provide a first widening section disposed between the arm base section and the resonating arm section.

According to this application example of the invention, although the asymmetry property due to the etching anisotropy of the piezoelectric material is caused by the difference between the arm width of the arm base section and the arm width of the resonating arm section, the arm width of the first widening section is gradually increased from the arm width of the resonating arm section to the arm width of the arm base section in accordance with the difference between the arm width of the arm base section and the arm width of the resonating arm section, thereby suppressing the asymmetry property of the etching due to the anisotropy of the piezoelectric material. Thus, it becomes possible to provide symmetry property with respect to the vibration direction (the amplitude direction) between the resonating arm sections and the arm base sections. In such a manner as described above, balance can be maintained between the plurality of resonating arm sections, and thus the vibration characteristics of the piezoelectric resonator element can be stabilized.

### APPLICATION EXAMPLE 3

According to this application example of the invention, in the piezoelectric resonator element of the above application example of the invention, it is preferable to provide a second widening section disposed between the base portion and the arm base section.

According to this application example of the invention, although the asymmetry property due to the etching anisotropy of the piezoelectric material is caused between the base portion and the arm base sections, the arm width of the second widening section disposed between the base portion and the arm base section is gradually increased from the arm width of the arm base section to the width of the base portion to thereby suppress the asymmetry property of etching due to the anisotropy of the piezoelectric material. Thus, it becomes possible to provide symmetry property with respect to the vibration direction (the amplitude direction) between the base portion and the arm base sections. In such a manner as described above, balance can be maintained between the plurality of resonating arm sections, and thus the vibration characteristics of the piezoelectric resonator element can be stabilized.

### APPLICATION EXAMPLE 4

According to this application example of the invention, there is provided a piezoelectric device including the piezoelectric resonator element according to any one of the application examples of the invention described above, and a package adapted to house the piezoelectric resonator element.

According to this application example of the invention, since the arm base sections each having the arm width larger than the arm width of the resonating arm section and smaller than the pitch of the plurality of the resonating arm sections are provided, and the arm base sections each have a portion having a width larger than the arm width of the resonating arm section and having a certain length to thereby provide rigidity to the resonating arm sections, it is possible to obtain the piezoelectric device, which prevents the vibration of the resonating arm section from leaking to the base portion to thereby stabilize the vibration of the resonating arm section and the vibrational frequency of the piezoelectric resonator element.

### APPLICATION EXAMPLE 5

According to this application example of the invention, there is provided a piezoelectric device including the piezoelectric resonator element according to any one of the application examples of the invention described above, a drive circuit electrically connected to the piezoelectric resonator element, and a package adapted to house the piezoelectric resonator element and the drive circuit.

According to this application example of the invention, since the arm base sections each having the arm width larger than the arm width of the resonating arm section and smaller than the pitch of the plurality of the resonating arm sections are provided, and the arm base sections each have a portion having a width larger than the arm width of the resonating arm section and having a certain length to thereby provide rigidity to the resonating arm sections, it is possible to prevent the vibration of the resonating arm section from leaking to the base portion to thereby stabilize the vibration of the resonating arm section and the vibrational frequency of the piezoelectric resonator element, and further, since the drive circuit is housed, a small-sized piezoelectric device can be obtained.

### APPLICATION EXAMPLE 6

According to this application example of the invention, there is provided an electronic apparatus including the piezoelectric resonator element according to any one of the application examples of the invention described above.

According to this application example of the invention, since the piezoelectric resonator element with the stabilized vibration of the resonating arm section and the stabilized vibrational frequency is used, the electronic apparatus having the stable electrical characteristics can be provided.

### BRIEF DESCRIPTION OF THE DRAWINGS

The invention will be described with reference to the accompanying drawings, wherein like numbers reference like elements.

FIGS. 1A through 1C are schematic configuration diagrams showing a quartz crystal resonator element according to a first embodiment.

FIGS. 2A through 2E are schematic plan views showing modified examples regarding an arm base section in the first embodiment.

FIGS. 3A and 3B are schematic configuration diagrams showing a quartz crystal resonator according to a second embodiment.

FIG. 4 is a schematic cross-sectional view showing a quartz crystal oscillator according to a third embodiment.

FIG. 5 is a perspective view schematically showing a cellular phone as an example of an electronic apparatus according to the invention.

FIG. 6 is a circuit block diagram of the cellular phone as the example of the electronic apparatus according to the invention.

FIG. 7 is a perspective view schematically showing a personal computer as an example of an electronic apparatus according to the invention.

### DESCRIPTION OF EXEMPLARY EMBODIMENTS

In the explanation of the embodiment described below, a quartz crystal resonator element using a quartz crystal, which is a piezoelectric material, as a piezoelectric resonator element, and a quartz crystal device using the quartz crystal resonator element as a piezoelectric device will be cited as an example.

### First Embodiment

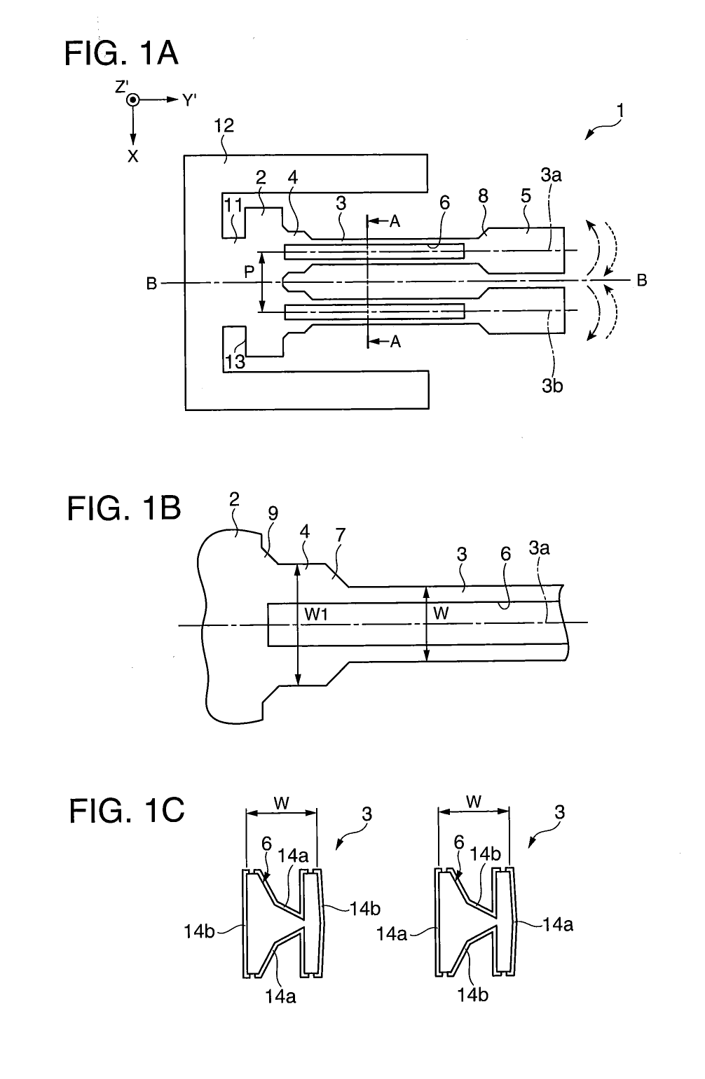

A first embodiment of the invention will hereinafter be explained with reference to FIGS. 1A through 1C.

FIG. 1A is a schematic plan view showing the quartz crystal resonator element according to the first embodiment. FIG. 1B is a partial enlarged view of the quartz crystal resonator element shown in FIG. 1A. FIG. 1C is a cross-sectional view along the line A-A shown in FIG. 1A.

As shown in FIG. 1A, the quartz crystal resonator element 1 has a Z-axis as an optical axis of the quartz crystal column, an X-axis as an electrical axis perpendicular to the Z-axis, and a Y-axis as a mechanical axis perpendicular to the x-axis, and is cut out from a Z-quartz crystal plate along a plane obtained by tilting the X-Y plane 5 degrees from the angle of 0 degree around the X-axis viewed from the intersection (the coordinate origin) between the X-axis and the Y-axis. As shown in FIGS. 1A through 1C, the width direction of the base portion 2 corresponds to the X-axis, the longitudinal direction of the resonating arm section 3 corresponds to a Y′-axis direction, and the thickness direction of the quartz crystal resonator element 1 corresponds to a Z′-axis direction.

Further, the quartz crystal resonator element 1 is provided with the base portion 2, two resonating arm sections 3, two arm base sections 4, two tip weight sections 5, elongated groove sections 6, weight widening sections 8, a coupling section 11, and a support section 12.

The coupling section 11 is formed so as to extend from the base portion 2. The support section 12 is formed so as to extend from the coupling section 11. The coupling section 11 is formed to have a dimension in the vertical direction shown in the drawing smaller than the dimension of the base portion 2 and the dimension of the support section 12 in the vertical direction shown in the drawing. Thus, cut sections 13 are formed between the base portion 2 and the support section 12.

The two resonating arm sections 3 are formed so as to extend from the base portion 2 in parallel to each other to have an arm width W. It should be noted that the expression of “in parallel to each other” denotes the state in which the respective extending directions of the resonating arm sections 3 are parallel to each other. The arm base sections 4 each have an arm width W1 larger than the arm width W of the resonating arm section 3, and are formed on the side of the base portion 2. The two resonating arm sections 3 are disposed at an interval P.

The tip weight sections 5 each have an arm width larger than the arm width W of the resonating arm section 3, and are formed on the tips of the respective resonating arm sections 3. The resonating arm sections 3, the arm base sections 4, and the tip weight sections 5 are each formed axisymmetrically about the dashed dotted line denoted as B-B in FIG. 1A.

Between the resonating arm section 3 and the tip weight section 5, there is formed the weight widening section 8 for gradually increasing the arm width from the arm width W of the resonating arm section 3 to the arm width of the tip weight section 5.

As shown in FIG. 1B, between the resonating arm section 3 and the arm base section 4 there is formed a first widening section 7 extending from the resonating arm section 3 so as to gradually increase the arm width from the arm width W of the resonating arm section 3 to the arm width W1 of the arm base section 4.

Between the arm base section 4 and the base portion 2, there is formed a second widening section 9 for gradually increasing the arm width from the arm width W1 of the arm base section 4 to the width of the base portion 2. In other words, the resonating arm section 3 extends to the base portion 2 via the arm base section 4. In a detailed description, the resonating arm section 3 extends to the arm base section 4 having the arm width W1 via the first widening section 7, and further extends from the arm base section 4 to the base portion 2 via the second widening section 9.

In the present embodiment, the positions bisecting the respective arm widths W, W1 are arranged so as to line on the straight line indicated by the dashed dotted line 3a shown in FIG. 1B. In other words, the resonating arm section 3 and the arm base section 4 are each formed axisymmetrically about the dashed dotted line 3a shown in FIG. 1B.

Further, since the tip weight sections 5 are formed axisymmetrically about the dashed dotted line denoted as B-B in FIG. 1A, the arm width of the tip weight section 5 takes a value smaller than the pitch P of the resonating arm sections 3. In other words, the arm width of the tip weight section 5 has a value smaller than the distance (denoted as the pitch P in the drawing) between the dashed dotted line 3a as the imaginary centerline of one of the resonating arm sections 3 and the dashed dotted line 3b as the imaginary centerline of the other of the resonating arm sections 3.

The elongated groove section 6 is formed along the longitudinal direction of the resonating arm section 3. As shown in FIG. 1C, the elongated groove section 6 is provided to each of the surfaces having the arm width W.

As shown in FIG. 1C, excitation electrodes 14a, 14b are provided to the respective resonating arm sections and the elongated groove sections 6. Further, the layouts of the respective excitation electrodes 14a, 14b are reverse to each other between the resonating arm section 3 (the elongated groove sections 6) on the left side and the resonating arm section 3 (the elongated groove sections 6) on the right side. Specifically, the excitation electrode 14a is disposed in each of the elongated groove sections 6 on the left side of the drawing, while the excitation electrode 14b is disposed in each of the elongated groove sections 6 on the right side of the drawing. Further, the excitation electrodes 14b are disposed in the resonating arm section 3 on the left side of the drawing, while the excitation electrodes 14a are disposed in the resonating arm section 3 on the right side of the drawing.

The electrical field is generated by making the current flow between the excitation electrode 14a and the excitation electrode 14b, and the resonating arm section 3 vibrates due to the piezoelectric effect to drive the quartz crystal resonator element 1 as illustrated with the dashed dotted arrows and the dashed arrows in FIG. 1A.

According to the present embodiment, since the arm base sections 4 each having the arm width W1 larger than the arm width W of the resonating arm section 3 and smaller than the pitch P of the two resonating arm sections 3 are provided, and the arm base sections 4 each have a portion having a width larger than the arm width W of the resonating arm section 3 and having a certain length to thereby provide rigidity to the resonating arm sections 3, it is possible to prevent the vibration of the resonating arm section 3 from leaking to the base portion 2 to thereby stabilize the vibration of the resonating arm section 3 and the vibrational frequency of the quartz crystal resonator element 1.

Further, although the asymmetry property due to the etching anisotropy of the piezoelectric material is caused by the difference between the arm width W1 of the arm base section 4 and the arm width W of the resonating arm section 3, the arm width of the first widening section is gradually increased from the arm width W of the resonating arm section 3 to the arm width W1 of the arm base section 4 in accordance with the difference between the arm width W1 of the arm base section 4 and the arm width W of the resonating arm section 3, thereby suppressing the asymmetry property of the etching due to the anisotropy of the piezoelectric material.

Thus, it becomes possible to provide a symmetry property with respect to the vibration direction (the amplitude direction) between the resonating arm sections 3 and the arm base sections 4. In such a manner as described above, balance can be maintained between the two resonating arm sections 3, and thus the vibration characteristics of the quartz crystal resonator element 1 can be stabilized.

Further, although the asymmetry property due to the etching anisotropy of the piezoelectric material is caused between the base portion 2 and the arm base sections 4, the arm width of the second widening section 9 disposed between the base portion 2 and the arm base section 4 is gradually increased from the arm width of the arm base section 4 to the width of the base portion 2 to thereby suppress the asymmetry property of etching due to the anisotropy of the piezoelectric material. Thus, it becomes possible to provide a symmetry property with respect to the vibration direction (the amplitude direction) between the arm base sections 4 and the second widening sections 9. In such a manner as described above, balance can be maintained between the two resonating arm sections 3, and thus the vibration characteristics of the quartz crystal resonator element 1 can be stabilized.

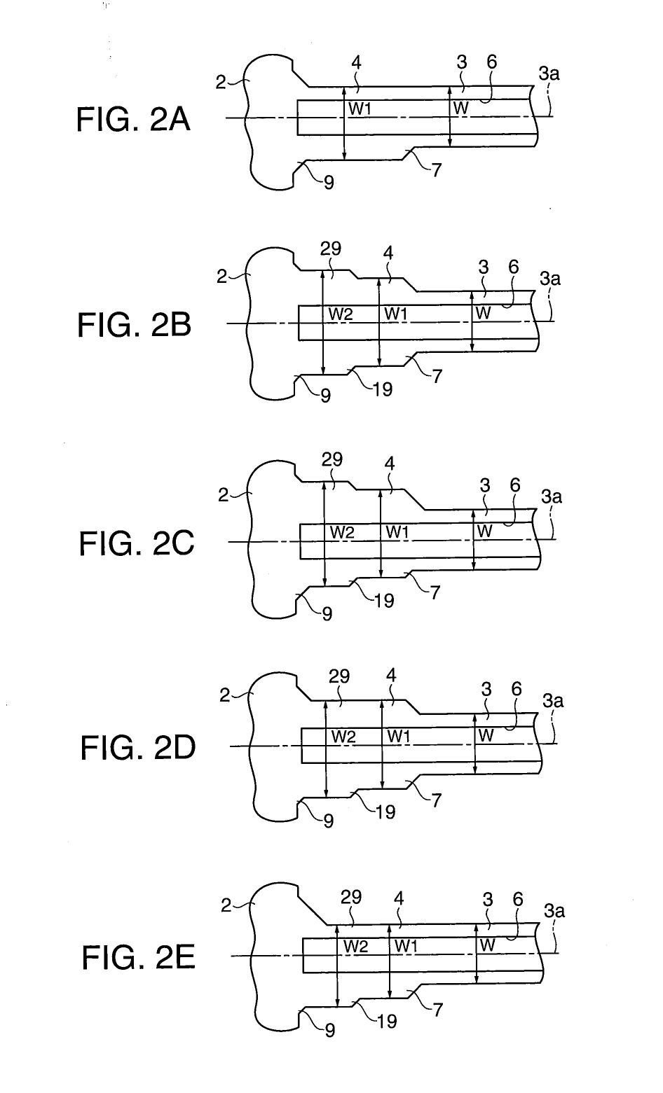

Some modified examples regarding the arm base sections 4 in the first embodiment will hereinafter be explained with reference to FIGS. 2A through 2E.

### FIRST MODIFIED EXAMPLE

FIG. 2A shows a first modified example. As shown in FIG. 2A, each of the arm base sections 4 of the first modified example is not formed axisymmetrically about the dashed dotted line 3a.

One end of the arm base section 4 defining the arm width W1 and one end of the resonating arm section 3 defining the arm width W are formed on the same straight line.

### SECOND MODIFIED EXAMPLE

FIG. 2B shows a second modified example. As shown in FIG. 2B, each of the arm base sections 4 of the second modified example is provided with a third widening section 19 and a base section 29 having an arm width W2 on the side of the base portion 2. The arm base section 4 and the base section 29 are formed axisymmetrically about the dashed dotted line 3a.

Further, although it is assumed in the second modified example that the arm base section 4 and the base section 29 are formed axisymmetrically about the dashed dotted line 3a, the configuration is not limited thereto, and it is also possible to assume that both of the arm base section 4 and the base section 29 are not formed axisymmetrically about the dashed dotted line 3a as shown in FIG. 2C.

Further, it is also possible to assume that one of the arm base section 4 and the base section 29 is not formed axisymmetrically about the dashed dotted line 3a, and the other thereof is formed axisymmetrically about the dashed dotted line 3a.

Further, in the second modified example, although the three widening sections, namely the first widening section 7, the second widening section 9, and the third widening section 19, are formed between the resonating arm section 3 and the base portion 2, it is also possible to form four or more widening sections.

### THIRD MODIFIED EXAMPLE

FIG. 2D shows a third modified example. As shown in FIG. 2D, the arm base section 4 of the third modified example is formed axisymmetrically about the dashed dotted line 3a while the base section 29 is not formed axisymmetrically about the dashed dotted line 3a similarly to the second modified example. One end of the arm base section 4 defining the arm width W1 is formed on the same straight line as one end of the base section 29 defining the arm width W2, but is not formed on the same straight line as the one end of the resonating arm section 3 defining the arm width W.

Further, in the third modified example, although it is assumed that the base section 29 is not formed axisymmetrically about the dashed dotted line 3a, the configuration is not limited thereto, but it is also possible to assume that the base section 29 is formed axisymmetrically about the dashed dotted line 3a while the arm base section 4 is not formed axisymmetrically about the dashed dotted line 3a.

### FOURTH MODIFIED EXAMPLE

FIG. 2E shows a fourth modified example. As shown in FIG. 2E, each of the arm base sections 4 and each of the base sections 29 of the fourth modified example are not formed axisymmetrically about the dashed dotted line 3a. One end of the arm base section 4 defining the arm width W1 and one end of the base section 29 defining the arm width W2 are formed on the same straight line as the one end of the resonating arm section 3 defining the arm width W.

### Second Embodiment

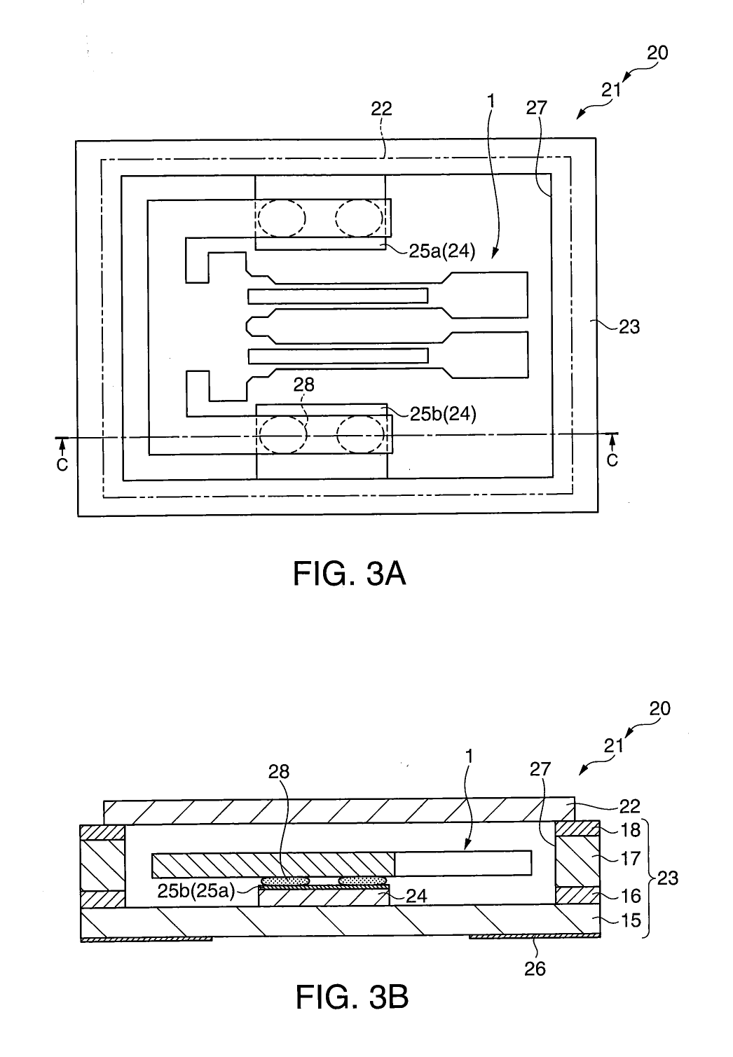

A second embodiment of the invention will hereinafter be explained with reference to FIGS. 3A and 3B.

The quartz crystal device according to the second embodiment is a quartz crystal resonator using the quartz crystal resonator element according to the first embodiment shown in FIGS. 1A through 1C, the constituents identical to those of the first embodiment are denoted by the same reference numerals, and the explanations of the constituents will be omitted.

FIG. 3A is a schematic plan view showing the quartz crystal resonator according to the second embodiment. FIG. 3B is a cross-sectional view along the line C-C shown in FIG. 3A.

The point in which the quartz crystal resonator according to the second embodiment is different from the quartz crystal resonator element according to the first embodiment is that the quartz crystal resonator is provided with a package for housing the quartz crystal resonator element.

As shown in FIGS. 3A and 3B, the quartz crystal resonator 20 is provided with the quartz crystal resonator element 1 and the package 21. The quartz crystal resonator element 1 is housed in the package 21 in an airtight manner. The package 21 is provided with a base 23 and a lid member 22.

The base 23 is provided with a base substrate 15, layer substrates 16, 17, a bonding section 18, conductive fixing sections 25a, 25b, external connection terminals 26, and a housing chamber 27.

The base 23 is formed by sequentially stacking the layer substrates 16, 17 on the base substrate 15, and then forming the bonding section 18 made of metal, soldering material, glass or the like on the layer substrates 16, 17. The base substrate 15 and the layer substrates 16, 17 are formed of a ceramic sheet made of an aluminum oxide material as an insulating material, for example. The housing chamber 27 is formed by hollowing out the layer substrates 16, 17 so as to conform with the shape of the housing chamber 27, stacking the layer substrates 16, 17 on the base substrate 15, and then sintering the constituents.

There are provided two projection sections 24 formed of the base substrate 15 extending inside the housing chamber 27. On the projection sections 24, there are formed the conductive fixing sections 25a, 25b, respectively. The conductive fixing sections 25a, 25b are formed by sequentially performing the processes of, for example, tungsten metalizing, nickel plating, and gold plating.

Two external connection terminals 26 are provided, and are formed on the lower surface of the base substrate 15, the outside of the base 23, namely the surface opposed to the housing chamber 27. The external connection terminals 26 are formed on the lower surface of the base substrate 15 by sequentially performing the processes of, for example, tungsten metalizing, nickel plating, and gold plating.

Further, the external connection terminals 26 are electrically connected to the conductive fixing sections 25 via, for example, wiring (not shown) provided to the base substrate 15.

The support section 12 of the quartz crystal resonator element 1 is provided with mounting electrodes (not shown) and are connected respectively to the excitation electrodes 14a, 14b. The quartz crystal resonator element 1 is fixed to the conductive fixing section 25 with an electrically conductive adhesive 28, and is disposed inside the housing chamber 27 provided to the base 23. In such a manner as described above, the excitation electrodes 14a, 14b are electrically connected respectively to the conductive fixing sections 25a, 25b, and further electrically connected respectively to the external connection terminals 26.

The electrically conductive adhesive 28 is made of, for example, silicon resin, epoxy resin, or polyimide resin, and contains a combination of electrically conductive powder such as silver (Ag) or platinum (Pt).

The base 23 is bonded to the lid member 22 with the bonding section 18. In such a manner as described above, the quartz crystal resonator element 1 is encapsulated in the housing chamber 27 in an airtight manner with the base 23 and the lid member 22.

The lid member 22 is made of metal such as iron (Fe), cobalt (Co), or nickel (Ni), an alloy containing a combination of any of these metals, ceramics composed of an aluminum oxide material, or glass.

According to the present embodiment, since the arm base sections 4 each having the arm width W1 larger than the arm width W of the resonating arm section 3 and smaller than the pitch P of the two resonating arm sections 3 are provided, and the arm base sections 4 each have a portion having a width larger than the arm width W of the resonating arm section 3 and having a certain length to thereby provide rigidity to the resonating arm sections 3, it is possible to obtain the quartz crystal resonator 20, which prevents the vibration of the resonating arm section 3 from leaking to the base portion 2 to thereby stabilize the vibration of the resonating arm section 3 and the vibrational frequency of the quartz crystal resonator element 1.

Further, although the asymmetry property due to the etching anisotropy of the piezoelectric material is caused by the difference between the arm width of the arm base section 4 and the arm width of the resonating arm section 3, the arm width of the first widening section 7 is gradually increased from the arm width of the resonating arm section 3 to the arm width of the arm base section 4 in accordance with the difference between the arm width of the arm base section 4 and the arm width of the resonating arm section 3, thereby suppressing the asymmetry property of the etching due to the anisotropy of the piezoelectric material. Thus, it becomes possible to provide symmetry property with respect to the vibration direction (the amplitude direction) between the resonating arm sections 3 and the arm base sections 4. In such a manner as described above, balance can be maintained between the two resonating arm sections 3, and thus the quartz crystal resonator 20, which stabilizes the vibration characteristics of the quartz crystal resonator element 1, can be obtained.

Further, although the asymmetry property due to the etching anisotropy of the piezoelectric material is caused between the base portion 2 and the arm base sections 4, the arm width of the second widening section 9 disposed between the base portion 2 and the arm base section 4 is gradually increased from the arm width of the arm base section 4 to the width of the base portion 2 to thereby suppress the asymmetry property of etching due to the anisotropy of the piezoelectric material. Thus, it becomes possible to provide a symmetry property with respect to the vibration direction (the amplitude direction) between the arm base sections 4 and the second widening sections 9. In such a manner as described above, balance can be maintained between the two resonating arm sections 3, and thus the quartz crystal resonator 20, which stabilizes the vibration characteristics of the quartz crystal resonator element 1, can be obtained.

### Third Embodiment

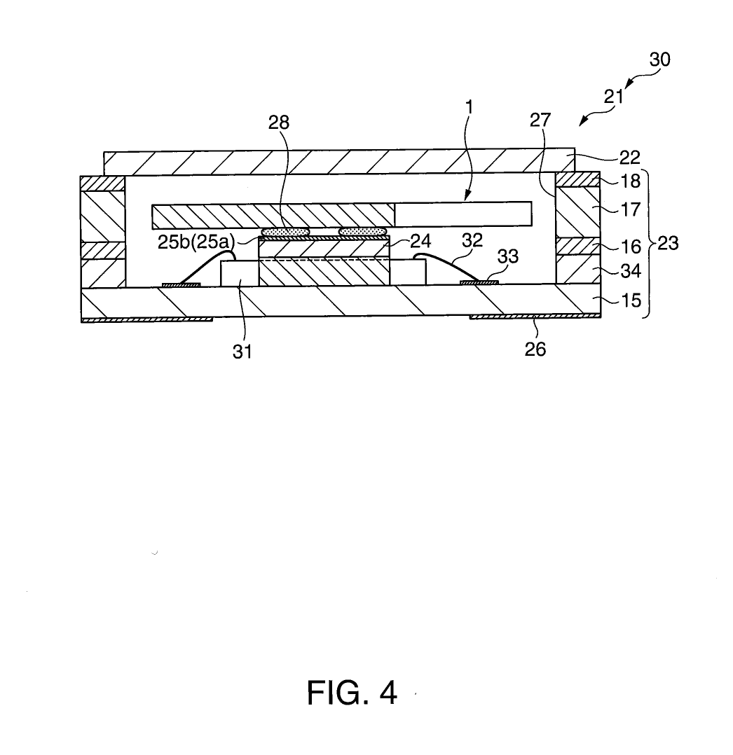

A third embodiment of the invention will hereinafter be explained with reference to FIG. 4.

The quartz crystal device according to the third embodiment is a quartz crystal oscillator using the quartz crystal resonator element according to the first embodiment shown in FIGS. 1A through 1C, the constituents identical to those of the first embodiment are denoted by the same reference numerals, and the explanations of the constituents will be omitted.

The point in which the quartz crystal oscillator according to the third embodiment is different from the quartz crystal resonator according to the second embodiment is that the quartz crystal oscillator is provided with a drive circuit electrically connected to the quartz crystal resonator and for driving the quartz crystal resonator.

As shown in FIG. 4, the quartz crystal oscillator 30 is provided with the quartz crystal resonator element 1, the package 21, and the drive circuit 31. The quartz crystal resonator element 1 and the drive circuit 31 are housed in the package 21 in an airtight manner. The package 21 is provided with the base 23 and the lid member 22.

The base 23 is provided with a layer substrate 34. The base 23 is formed by sequentially stacking the layer substrates 34, 16, and 17 on the base substrate 15, and then forming the bonding section 18 made of metal, soldering material, glass or the like on the layer substrate 17.

The drive circuit 31 is die-attached to the surface of the base substrate 15, and is connected to the internal connection terminals 33 via bonding wires 32.

The conductive fixing sections 25 are formed on the projection sections 24 of the layer substrate 16 inside the housing chamber 27.

A plurality of internal connection terminals 33 is provided, and is formed on the upper surface of the base substrate 15, the inside of the base 23, namely inside the housing chamber 27. The internal connection terminals 33 are formed on the upper surface of the base substrate 15 by sequentially performing the processes of, for example, tungsten metalizing, nickel plating, and gold plating.

Further, the internal connection terminals 33 are electrically connected to the conductive fixing sections 25 and the external connection terminals 26 via, for example, wiring (not shown) provided to the base substrate 15.

According to the present embodiment, since the arm base sections 4 each having the arm width W1 larger than the arm width W of the resonating arm section 3 and smaller than the pitch P of the two resonating arm sections 3 are provided, and the arm base sections 4 each have a portion having a width larger than the arm width W of the resonating arm section 3 and having a certain length to thereby provide rigidity to the resonating arm sections 3, it is possible to obtain the quartz crystal oscillator 30, which prevents the vibration of the resonating arm section 3 from leaking to the base portion 2 to thereby stabilize the vibration of the resonating arm section 3 and the vibrational frequency of the quartz crystal resonator element 1.

Further, although the asymmetry property due to the etching anisotropy of the piezoelectric material is caused by the difference between the arm width of the arm base section 4 and the arm width of the resonating arm section 3, the arm width of the first widening section 7 is gradually increased from the arm width of the resonating arm section 3 to the arm width of the arm base section 4 in accordance with the difference between the arm width of the arm base section 4 and the arm width of the resonating arm section 3, thereby suppressing the asymmetry property of the etching due to the anisotropy of the piezoelectric material. Thus, it becomes possible to provide symmetry property with respect to the vibration direction (the amplitude direction) between the resonating arm sections 3 and the arm base sections 4. In such a manner as described above, balance can be maintained between the two resonating arm sections 3, and thus the quartz crystal oscillator 30, which stabilizes the vibration characteristics of the quartz crystal resonator element 1, can be obtained.

Further, although the asymmetry property due to the etching anisotropy of the piezoelectric material is caused between the base portion 2 and the arm base sections 4, the arm width of the second widening section 9 disposed between the base portion 2 and the arm base section 4 is gradually increased from the arm width of the arm base section 4 to the width of the base portion 2 to thereby suppress the asymmetry property of etching due to the anisotropy of the piezoelectric material. Thus, it becomes possible to provide a symmetry property with respect to the vibration direction (the amplitude direction) between the arm base sections 4 and the second widening sections 9. In such a manner as described above, balance can be maintained between the two resonating arm sections 3, and thus the quartz crystal oscillator 30, which stabilizes the vibration characteristics of the quartz crystal resonator element 1, can be obtained.

It should be noted that modifications, improvements, and so on within the range where at least a part of problems described above can be solved can be included in the embodiment described above.

For example, although in the explanation it is assumed that the quartz crystal resonator element is provided with the first widening section, the second widening section, and the third widening section, the configuration is not limited thereto, but it is also possible to assume that either of the first widening section, the second widening section, and the third widening section is not provided, or it is also possible to assume that all of the three widening sections, namely the first widening section, the second widening section, and the third widening section, are not provided. The number of widening sections can arbitrarily be selected.

Further, although in the explanation, it is assumed that the quartz crystal resonator element is provided with the connection section, the support section, and the cut sections, the configuration is not limited thereto, but the configuration without the support section can also be adopted. On this occasion, the mounting electrodes are provided to either one of the connection section and the base portion, and the quartz crystal resonator element is fixed to the conductive fixing sections with the electrically conductive adhesive, and is electrically connected thereto. Alternatively, the configuration of eliminating the support section, the connection section, and the cut sections can also be adopted. On this occasion, the mounting electrodes are provided to the base portion, and the quartz crystal resonator element is fixed to the conductive fixing sections with the electrically conductive adhesive, and is electrically connected thereto.

Further, although the thickness dimension (in the vertical direction in the drawing) of the quartz crystal resonator element is constant in the illustration of FIGS. 3A, 3B and 4, the configuration is not limited thereto, but the base portion, the arm base section, and so on constituting the quartz crystal resonator element can be different in thickness dimension from the resonating arm section. It should be noted that it is preferable that the resonating arm sections, the arm base sections, and so on constituting the quartz crystal resonator element denoted with the same names and the same reference numerals do not have the respective thickness dimensions different from each other.

Further, the package for housing the quartz crystal resonator is not limited to the embodiment described above, but can be of a so-called cylinder type made of metal such as iron (Fe), cobalt (Co), or nickel (Ni), or an alloy containing a combination of these metals. The electrically conductive adhesive can be solder.

Further, although the quartz crystal resonator and the quartz crystal oscillator are cited as examples of the piezoelectric device in the explanation, the piezoelectric device is not limited thereto, but can be a sensor such as a piezoelectric vibration gyro sensor. Further, although the explanation is presented using the quartz crystal as an example of the piezoelectric material, the piezoelectric material is not limited thereto, but the piezoelectric material such as lithium tantalate or lithium niobate can also be used.

Further, the material of the piezoelectric resonator element is not limited to the quartz crystal, but can be a piezoelectric substance such as lead zirconium titanate (PZT), zinc oxide (ZnO), aluminum nitride (AlN), lithium tantalate (LiTaO₃), lithium tetraborate (Li₂B₄O₇), lithium niobate (LiNbO₃).

### Electronic Apparatus

The quartz crystal resonator 20 and the quartz crystal oscillator 30 as the piezoelectric devices of the respective embodiments described hereinabove can be applied to various types of electronic apparatuses, and the electronic apparatuses thus obtained become high in reliability.

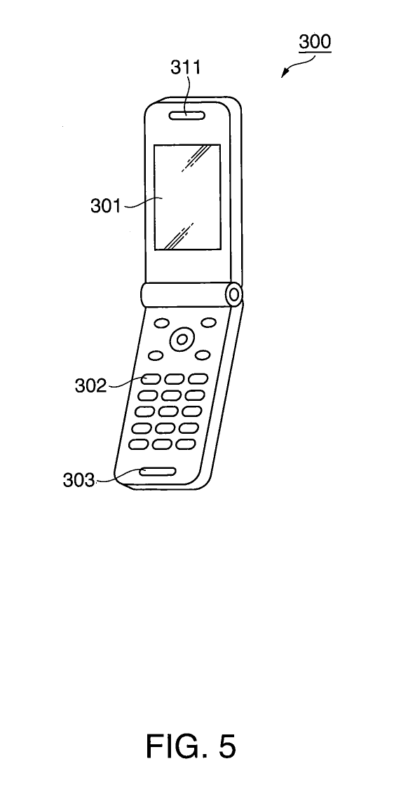

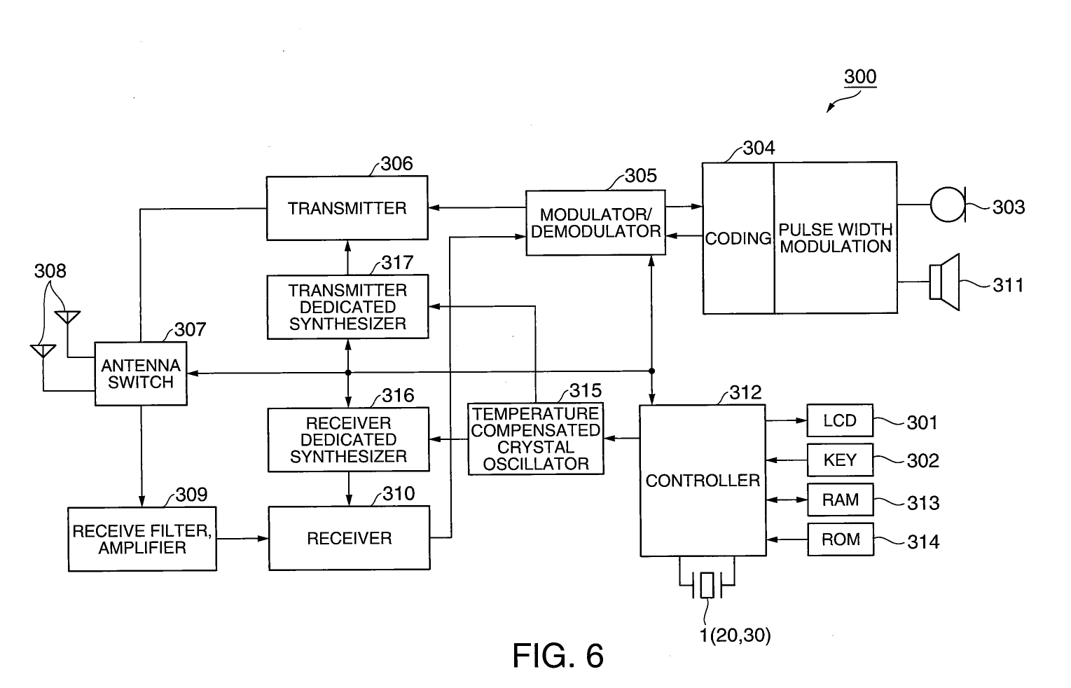

FIGS. 5 and 6 show a cellular phone as an example of the electronic apparatus according to the invention. FIG. 5 is a perspective view showing a schematic appearance of the cellular phone, and FIG. 6 is a circuit block diagram for explaining a circuit of the cellular phone.

The cellular phone 300 will be explained taking the quartz crystal oscillator 30 using the quartz crystal resonator element 1 described above as an example. Further, the explanation of the configurations and actions of the quartz crystal resonator element 1 and the quartz crystal oscillator 30 will be omitted. It should be noted that although the quartz crystal resonator 20 can be used instead of the quartz crystal oscillator 30, on this occasion, the drive circuit electrically connected to the quartz crystal resonator 20 and having the function of driving at least the quartz crystal resonator 20 is provided.

As shown in FIG. 5, the cellular phone 300 is provided with a liquid crystal display (LCD) 301 as the display section, keys 302 as an input section of the numerical characters and so on, a microphone 303, a speaker 311, a circuit not shown, and so on.

As shown in FIG. 6, in the case of performing the transmission in the cellular phone 300, when the user inputs his or her voice to the microphone 303, it results that the signal passes through the pulse width modulation/coding block 304 and the modulator/demodulator block 305, and is then transmitted from the antenna 308 via a transmitter 306 and an antenna switch 307.

Incidentally, a signal transmitted from a cellular phone of another person is received by the antenna 308, and then input from a receiver 310 to the modulator/demodulator block 305 via the antenna switch 307 and a receive filter 309. Further, it is arranged that the signal modulated or demodulated passes through the pulse width modulation/coding block 304, and is then output from the speaker 311 as a voice.

There is provided a controller 312 for controlling the antenna switch 307, the modulator/demodulator block 305, and so on among these constituents.

The controller 312 also controls the LCD 301 as the display section, the keys 302 as the input section for the numerical characters and so on, and further a RAM 313, a ROM 314, and so on besides the constituents described above, and is therefore required to be highly accurate. Further, downsizing of the cellular phone 300 is also required.

As the device corresponding to such a requirement, the quartz crystal resonator element 1 described above is used.

It should be noted that although the cellular phone 300 is also provided with a temperature compensated crystal oscillator 315, a receiver dedicated synthesizer 316, a transmitter dedicated synthesizer 317, and so on as additional constituent blocks, the explanation therefor will be omitted.

The quartz crystal resonator element 1 described above and used in the cellular phone 300 is capable of preventing the vibration of the resonating arm section 3 from leaking into the base portion side as described above, and is therefore capable of stabilizing the vibrational frequency. Further, the quartz crystal oscillator 30 as the piezoelectric device described in the above application example is provided with the drive circuit 31 electrically connected to the resonator element described above, and therefor can be made small-sized and can obtain the stable vibration characteristics.

Therefore, the electronic apparatus (the cellular phone 300) using the quartz crystal resonator element 1, the quartz crystal resonator 20, or the quartz crystal oscillator 30 becomes capable of keeping the stable characteristics.

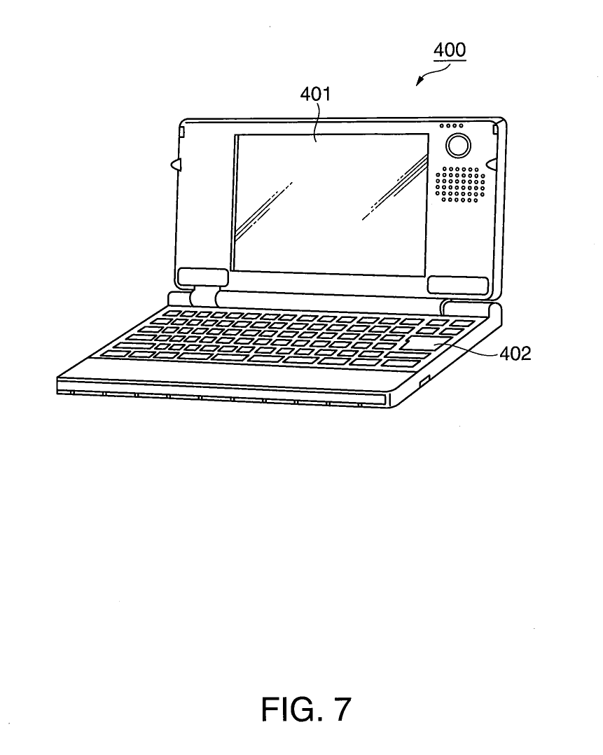

As the electronic apparatus mounting the piezoelectric oscillator 5 equipped with the quartz crystal resonator element 1 according to the invention, there can also be cited a personal computer (a mobile personal computer) 400 shown in FIG. 7. The personal computer 400 is provided with a display section 401, an input key section 402, and so on, and the quartz crystal resonator element 1 described above is used as the reference clock for electrical control therefor.

Further, as the electronic apparatus provided with the quartz crystal, resonator element 1 according to the invention, there can be cited in addition to the apparatuses described above, for example, a digital still camera, an inkjet ejection device (e.g., an inkjet printer), a laptop personal computer, a television set, a video camera, a video cassette recorder, a car navigation system, a pager, a personal digital assistance (including one with communication function), an electronic dictionary, an electric calculator, a computerized game machine, a word processor, a workstation, a video phone, a security video monitor, a pair of electronic binoculars, a POS terminal, a medical device (e.g., an electronic thermometer, an electronic manometer, an electronic blood sugar meter, an electrocardiogram measurement instrument, an ultrasonograph, and an electronic endoscope), a fish detector, various types of measurement instruments, various types of gauges (e.g., gauges for a vehicle, an aircraft, or a ship), and a flight simulator.

Although the electronic apparatuses according to the invention are described based on the embodiments shown in the accompanying drawings as described above, the present invention is not limited to these embodiments, but the configuration of each of the components can be replaced with one having an identical function and any configuration. Further, it is possible to add any other constituents to the invention. Further, the apparatus according to the invention can be a combination of any two or more configurations (features) out of the embodiments described above.

For example, although in the embodiments described above the case in which the quartz crystal resonator element has the two resonating arms as the vibrating sections is explained as an example, the number of resonating arms can also be three or larger.

Further, the quartz crystal resonator element explained in the embodiments described above can also be applied to a gyro sensor or the like besides the piezoelectric oscillators such as a voltage controlled crystal oscillator (VCXO), a temperature compensated crystal oscillator (TCXO), and an oven controlled crystal oscillator (OCXO).

The entire disclosure of Japanese Patent Application Nos: 2010-060327, filed Mar. 17, 2010 and 2010-292043, filed Dec. 28, 2010 are expressly incorporated by reference herein.

1. A piezoelectric resonator element comprising:
a base portion formed of a piezoelectric material; and
a plurality of resonating arm sections each extending from the base portion via an arm base section,
wherein an elongated groove section formed along a longitudinal direction of the resonating arm section is provided, and
the arm base section has an arm width, which is larger than an arm width of the resonating arm section and smaller than a distance between imaginary centerlines of the respective resonating arm sections in a width direction of the resonating arm section.

2. The piezoelectric resonator element according to claim 1, further comprising:
a first widening section disposed between the arm base section and the resonating arm section.

3. The piezoelectric resonator element according to claim 1, further comprising:
a second widening section disposed between the base portion and the arm base section.

4. A piezoelectric device comprising:
the piezoelectric resonator element according to claim 1; and
a package adapted to house the piezoelectric resonator element.

5. A piezoelectric device comprising:
the piezoelectric resonator element according to claim 1;
a drive circuit electrically connected to the piezoelectric resonator element; and
a package adapted to house the piezoelectric resonator element and the drive circuit.

6. An electronic apparatus comprising the piezoelectric resonator element according to claim 1.

7. A piezoelectric device comprising:
the piezoelectric resonator element according to claim 2; and
a package adapted to house the piezoelectric resonator element.

8. A piezoelectric device comprising:
the piezoelectric resonator element according to claim 3; and
a package adapted to house the piezoelectric resonator element.

9. A piezoelectric device comprising:
the piezoelectric resonator element according to claim 2;
a drive circuit electrically connected to the piezoelectric resonator element; and
a package adapted to house the piezoelectric resonator element and the drive circuit,

10. A piezoelectric device comprising:
the piezoelectric resonator element according to claim 3;
a drive circuit electrically connected to the piezoelectric resonator element; and
a package adapted to house the piezoelectric resonator element and the drive circuit.

11. An electronic apparatus comprising the piezoelectric resonator element according to claim 2.

12. An electronic apparatus comprising the piezoelectric resonator element according to claim 3.
